(19) United States
(12) Patent Application Publication
(10) Pub. No.: US 2005/0126493 A1
(43) Pub. Date: Jun. 16, 2005

(54) Linear or planar type evaporator for the controllable film thickness profile

(75) Inventor: Kwang-Ho Jeong, Goyang (KR)

Correspondence Address: GREENBLUM & BERNSTEIN, P.L.C., 1950 ROLAND CLARKE PLACE, RESTON, VA, 20191, US

(73) Assignee: Yonsei University, Seoul (KR)

(21) Appl. No.: 10/499,829

(22) PCT Filed: Jan. 22, 2003
(86) PCT No.: PCT/KR03/00136

(30) Foreign Application Priority Data
Jan. 22, 2002 (KR) 10-2002-0003544

(51) Int. Cl. C23C 16/00

(52) U.S. Cl. 118/726

(57) ABSTRACT

The present invention relates to an evaporator for manufacturing a thin film, and more particularly to a linear or planar type evaporator for evaporating and depositing a source material on a substrate located over the evaporator by using a slit with a certain pattern, comprising a crucible formed of an elongate barrel longitudinally extending to a predetermined distance to contain the material to be deposited therein; and a slit formed on the top surface of the crucible in the longitudinal direction of the crucible and having an area smaller than the sectional area of the crucible or a slit separately installed, thereby performing the deposition of a thin film by moving a substrate in a direction perpendicular to the longitudinal direction of the crucible. Therefore, the deposited thin film has improved uniformity of film thickness profile and a desired pattern.

### TECHNICAL FIELD

The present invention relates to an evaporator for manufacturing a thin film, and more particularly to a linear or planar type evaporator for the controllable film thickness profile having a slit with a specific pattern so that a deposited thin film has improved uniformity of film thickness profile and a desired pattern.

### BACKGROUND ART

In general, a thin film is manufactured by vapor deposition in various fields including semiconductor devices, organic electroluminescent elements and other optical coatings.

The vapor deposition is largely divided into PVD (Physical Vapor Deposition) and CVD (Chemical Vapor Deposition) and is widely used in both the industrial field for production of semiconductor devices and scientific research field.

Thermal evaporation, which is a typical way of the physical vapor deposition, has a defect that deposition of a large area is difficult, as compared to sputtering deposition. Most of evaporators which have been used up to date comprise an arrangement including an evaporator 1 wound with hot wire 3 and containing a source material 2 therein and a substrate 4 disposed at a predetermined distance from the evaporator and provided with a mask 5 on the evaporator side, in which the substrate 4 may be rotated in a tilted position, as shown in FIG. 1 and FIG. 2, for uniform deposition on a large area.

However, the deposition methods using an evaporator of this type have a problem in connection with efficiency in use of the source material 2. By such deposition methods, the distance between the substrate and the evaporator should be increased as the substrate is enlarged. When the distance between the substrate and the evaporator becomes great, a large amount of material evaporated from the evaporator may be deposited on the wall of vacuum chamber, though mainly deposited on the substrate. Consequently, efficiency in use of the source material 2 is remarkably reduced.

Furthermore, when the substrate is enlarged, there may occur a problem of the shadow effect resulting from an angle formed by the shadow mask 5 and the evaporator 1. This effect is generated since an angle formed by the middle part of the substrate and the evaporator is different from that formed by edges of the substrate and the evaporator.

In order to solve the above described problems, a plurality of evaporators is linearly arranged or a linear type evaporator is used by scanning a substrate or the linear type evaporator against each other.

However, in case of a plurality of evaporators, it is not easy to control the evaporation rates of the respective evaporators constantly at a desired level. Also, in case of the linear type evaporator, there is a problem in achieving uniform deposition due to the edge effect which occurs at edges of the substrate.

In practice, for a process of heating the linear type evaporator, it is not easy to control a temperature of every spot to a desired level. Even though every spot has the same evaporation rate, there always theoretically exist a difference between the middle part and the edge part. Therefore, in case of the linear type evaporator, such nonuniformity should be addressed.

Also, in the deposition methods by the linear type evaporator, the source or the substrate should be scanned for uniform deposition on the plane substrate. However, the movement of the source may cause problems such as electric contact due to movements of electric connecting parts and the scanning of the substrate requires a complex apparatus for moving the substrate. Therefore, development of a planar type evaporator will be very effective in terms of a breakdown and post management since the planar type evaporator does not need complicated movements of the substrate and source.

Also, whichever type the evaporator is of a planar type or a linear type, control of the thickness profile of a produced thin film is very important and if the thickness profile of the produced thin film can be controlled, it can be very useful in terms of application.

### DISCLOSURE OF THE INVENTION

Therefore, the present invention has been made in view of the above problems, and it is an object of the present invention to a linear type evaporator capable of producing a desired film thickness profile by controlling the evaporation rate at a spot of the evaporation according to its longitudinal position.

The linear type evaporator includes a crucible formed of an elongate barrel longitudinally extending to a predetermined distance for containing the material to be deposited therein; and a slit formed on the top surface of the crucible in the longitudinal direction of the crucible and having an area smaller than the sectional area of the crucible or a slit separately installed, thereby performing the deposition of a thin film by moving a substrate in a direction perpendicular to the longitudinal direction of the crucible.

In another aspect, the present invention provides a planar type evaporator which is completed by expanding the concept of the linear type evaporator to two dimension and does not need any movement of the material source and the substrate. The planar type evaporator includes a crucible formed of an elongate cylinder or polygonal prism having a sectional area relatively lager than its height to contain the material to be deposited therein; and a slit plane formed on the top surface of the crucible in the longitudinal direction of the crucible and having an area smaller than the sectional area of the crucible or a slit plane separately installed.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a schematic view showing a conventional point evaporator and the thickness profile of a deposited film;

FIG. 2 is a schematic view showing the deposition process using the conventional point evaporator;

FIG. 3 is a perspective view showing the linear type evaporator capable of controlling film thickness profile according to an embodiment of the present invention;

FIG. 4a is a side sectional view showing the planar type evaporator capable of controlling film thickness profile according to a first embodiment of the present invention;

FIG. 4b is a plan view showing the planar type evaporator capable of controlling film thickness profile according to a first embodiment of the present invention;

FIG. 5 is a plan view showing the planar type evaporator capable of controlling film thickness profile according to a first embodiment of the present invention;

FIG. 6a is a side sectional view showing the planar type evaporator capable of controlling film thickness profile according to a third embodiment of the present invention;

FIG. 6b is a plan view showing the planar type evaporator capable of controlling film thickness profile according to a third embodiment of the present invention;

FIG. 7 is a plan view showing the planar type evaporator capable of controlling film thickness profile according to a fourth embodiment of the present invention;

FIG. 8 is coordinates for calculation of flux at a position over the linear type and planar type evaporator capable of controlling film thickness profile according to the present invention; and

FIG. 9 is a graph showing the result of theoretical flux calculation according to substrate positions in FIG. 8.

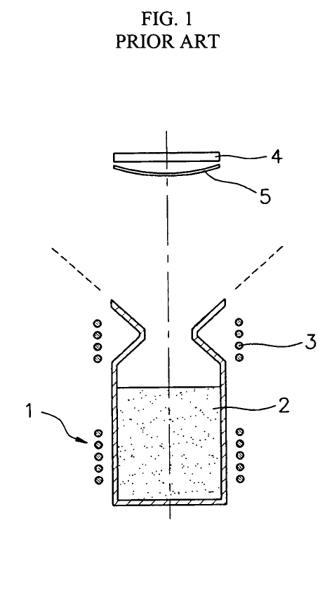

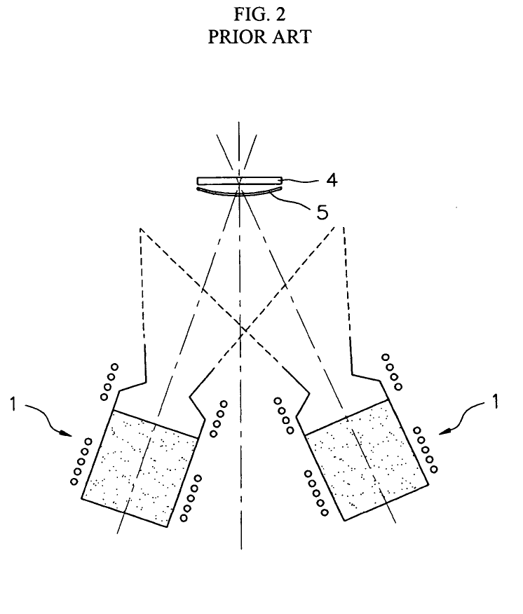

### BEST MODE FOR CARRYING OUT THE INVENTION

Now, the present invention will be described hereinafter in detail with reference to the accompanying drawings.

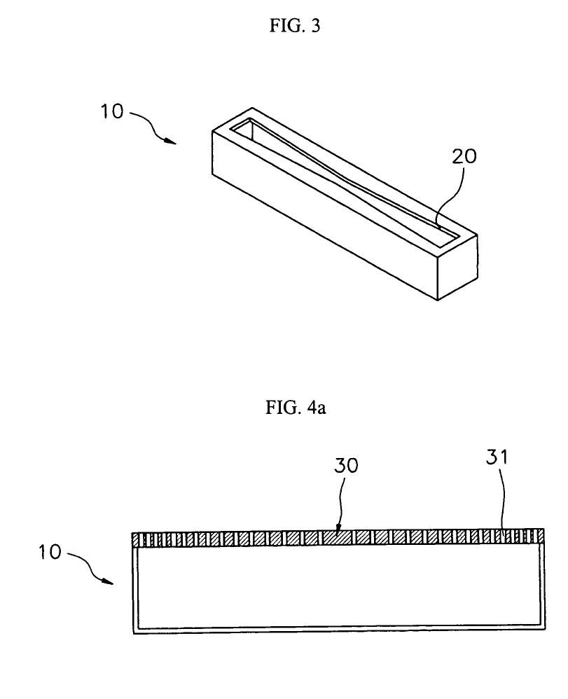

FIG. 3 is a perspective view showing the linear type evaporator capable of controlling film thickness profile according to an embodiment of the present invention.

The linear type evaporator capable of controlling film thickness profile includes a crucible 10 formed of an elongate barrel longitudinally extending to a predetermined distance for containing the material to be deposited therein; and a slit 20 formed on the top surface of the crucible 10 in the longitudinal direction of the crucible 10 and having an area smaller than the sectional area of the crucible 10 or a slit 20 separately installed, thereby performing the deposition of a thin film by moving a substrate in a direction perpendicular to the longitudinal direction of the crucible.

As shown in FIG. 3, the width of the slit 20 is large at both ends and gets narrower toward the center thereof. Accordingly, it is possible to prevent a deposited thin film from thickening at its center.

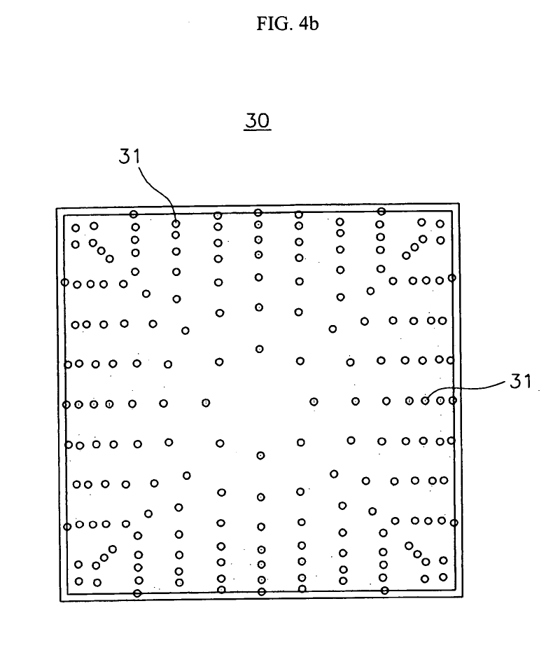

FIGS. 4a and 4b are a side section view and a plane view showing the planar type evaporator capable of controlling film thickness profile according to a first embodiment of the present invention, respectively. The planar type evaporator capable of controlling film thickness profile includes a crucible formed of an elongate cylinder or polygonal prism having a sectional area relatively lager than its height for containing the material to be deposited therein; and a slit plane formed on the top surface of the crucible in the longitudinal direction of the crucible and having an area smaller than the sectional area of the crucible or a slit plane separately installed, thereby performing the deposition of a thin film.

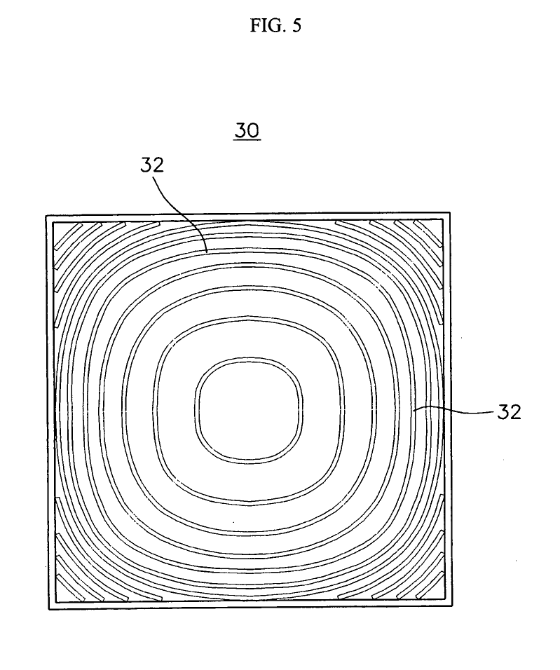

The slit plane 30, as shown in FIGS. 4a and 4b and FIG. 5, includes a plurality of circular slits 31 or narrow band-shaped slits 32 having a predetermined size. The circular slits 31 or narrow band-shaped slits are arranged more densely toward the periphery of the slit plane 30 than the center so that the uniformity of a thin film to be deposited is improved or, in some cases, a thin film is deposited with a desired pattern.

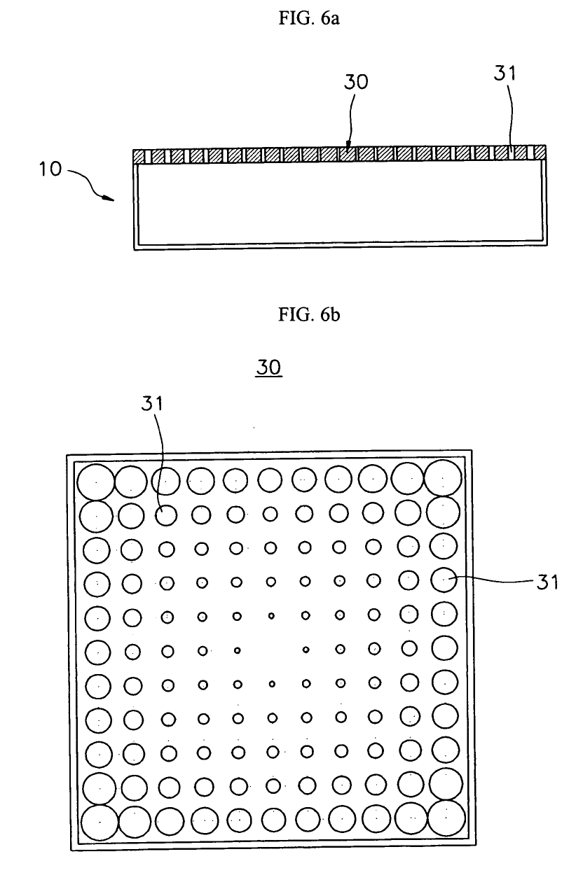

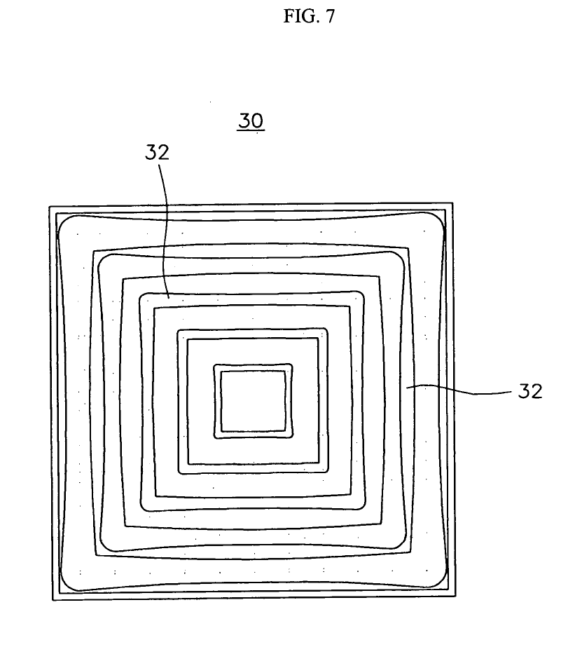

Also, as shown in FIGS. 6a and 6b and FIG. 7, the slit plane 30 includes a plurality of circular slits 31 or narrow band-shaped slits 32 having various sizes which are getting greater toward the periphery of the slit plane 30 than the center so as to obtain the same effect with the above construction.

As shown in FIG. 4a and FIG. 6a, the circular slits 31 having the same diameter are more densely spaced toward the periphery in the first embodiment of FIG. 4a while the circular slits 31 regularly spaced have different diameters which are getting greater toward the periphery in the third embodiment of FIG. 6a.

Theoretically, for the linear type evaporator, the thickness profile of a thin film in the longitudinal direction is presented as the sum total of flux (evaporation rate of deposition material per unit length) evaporated from every spot of the opening of the linear type evaporator. Since the linear type evaporator is conceptually a plurality of point evaporators standing in a line, the thickness profile is equal to the sum total of flux evaporated from every spot.

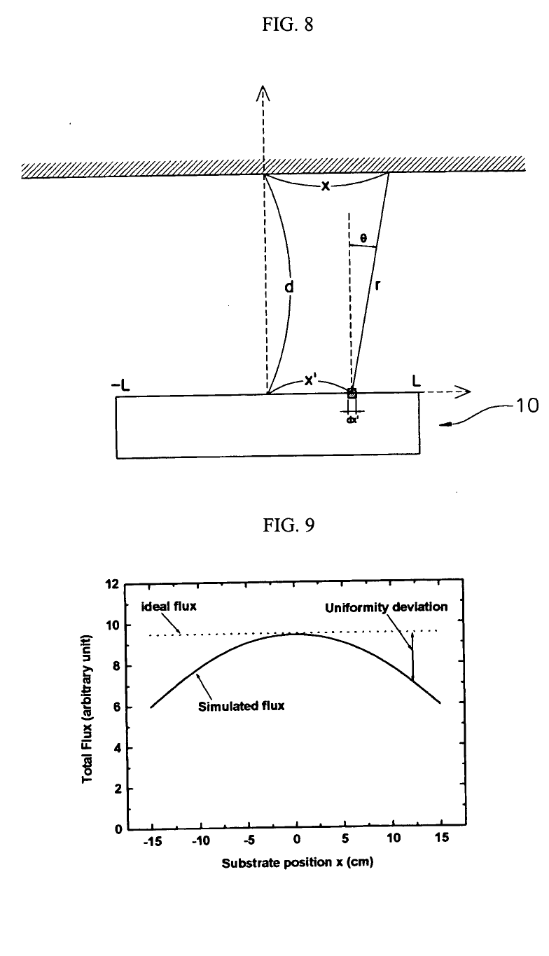

As shown in FIG. 8, a point evaporator and a position to be deposited are varied in distance and angle. A flux at a point where the distance is r and the angle is θ, is proportional to n^{th} power of Cosθ but is inversely proportional to the distance, as follows.

$$flux = \frac{{cos}^{n} θ}{{r}^{2}} \qquad ( 1 )$$

Therefore, the flux at a point on the surface deposited by the linear type evaporator shown in FIG. 8 can mathematically be represented as follows.

$$g ( x ) = {\int }_{- L}^{L} \frac{{cos}^{n} θ}{{r}^{2}} λ ( x ) ⅆ x \qquad ( 2 )$$

where λ(x) is an evaporation rate of the linear type evaporator per unit length and a function for an evaporate rate at a position in the longitudinal direction of the linear type evaporator. Therefore, by using this numerical expression, it is possible to give the flux at any position on the deposited surface over the linear type evaporator by means of a function according to the distance, and hence, to expect thickness of the thin film at that position.

Accordingly, if λ(x) can be controlled, the film thickness profile can be controlled, which will be very useful in terms of obtaining a desired film thickness profile in the deposition process. Specially, in general semiconductor and display processes, uniformity of a produced thin film is important. Thus, control of λ(x) can be very usefully used in the industrial fields.

In practice, the λ(x) control methods are divided into control of evaporation rate at a desired position, for example by temperature control and control of width of the opening. However, it is substantially very difficult to control the evaporation rate through temperature control according to the position of the linear type evaporator. Therefore, it is more suitable to control the source to emit a uniform evaporation rate as a whole, and then to adjust the width of the opening to obtain a desired thickness profile.

A useful method for controlling the source to emit a uniform evaporation rate throughout the linear type evaporator is as shown in FIG. 3. FIG. 3 shows a linear type evaporator conceptually having a uniform evaporation rate. The principle upon which the evaporator is based is as follows.

When the width of the opening is much smaller than that of the cross-section of the evaporator, as shown in FIG. 3, the pressure inside the crucible 10 is increased, unlike the outside of low vacuum (typically up to 10⁻⁵ Torr), since the number of gas molecules is large due to evaporation of the source material. A place with the vacuum of more than 10⁻² Torr is a viscous flow region where gas molecules vigorously collide with each other and thereby the partial pressure variation is small. Therefore, even though the evaporation rate of a source material is varied by temperature change at each point of the linear type evaporator, the pressure inside the crucible 10, that is, the number of gas molecules is equalized by collision between the gas molecules evaporated in the crucible 10, whereby a uniform flux can be emitted throughout the entire length of the linear type evaporator.

Once the linear type evaporator having a uniform flux is prepared, a linear type evaporator capable of controlling the film thickness profile can be produced by suitably adjusting the width of the opening. The following Equation (3) relates to the width of the slit for obtaining a specific film thickness profile f(x).

$$w ( x ) = w ( 0 ) \frac{f ( x )}{g ( x )} = \frac{w ( 0 ) f ( x )}{{\int }_{- L}^{L} \frac{{cos}^{n} θ}{{r}^{2}} λ ( {x}^{′} ) ⅆ {x}^{′}} \qquad ( 3 )$$

Where w(0) represents a width at a position with a distance of x from the center, that is, a function represented according to the position to calculate the slit width at that position for obtaining the specific film thickness profile f(x), and w(0) represents the width of the slit at a datum point, i.e., the center. Therefore, once the specific film thickness profile is decided, a function for the slit width can be determined according the above equation.

Here, the method for adjusting the slit width includes various methods, from methods by controlling the evaporator's own shape, that is, by adjusting the cross-sectional width of the crucible to methods by adjusting only the width of the slit 20 and more over, methods by installing a separate slit 20 on the opening formed with a cover.

The shape of the slit 20 in the opening can be determined by the Expression (2). If λ(α)=constantly λ, when the integral in the Expression 2 is calculated, the result is various by the value of n (1, 2 . . . ) according to the shape of the evaporator. Usually, the expression is calculated at a low order, that is, n=1 or 2. For example, where n=1 and λ (x)=λ, the result is as follows:

$$g ( x ) = \frac{λ}{d} [ \frac{x + \frac{L}{2}}{\sqrt{{d}^{2} + {( x + \frac{L}{2} )}^{2}}} - \frac{( x - \frac{L}{2} )}{\sqrt{{d}^{2} + {( x - \frac{L}{2} )}^{2}}} ] \qquad ( 4 )$$

A graph simulated by the above resulting Expression (4) is shown in FIG. 9. The graph shows the fluxes at various points on a sample surface located at 15 cm over a linear type evaporator having a length of 30 cm, as calculated by the above Expression (4). As can be seen from the result, the simulated flux curve has a significant deviation from the ideal flux curve. Accordingly, there is a need of a process for compensation of the flux to obtain a uniform thin film. Thus, the slit-like opening can be enlarged as much as the flux deviation of the simulated flux from the ideal flux to obtain a uniform flux. The slit width to obtain a uniform thin film (f(x)=f(0): constant) can be expressed by the following Expression (5) based on the above described theory.

$$w ( x ) = w ( 0 ) \frac{f ( 0 )}{g ( x )} = \frac{w ( 0 ) f ( 0 )}{\frac{λ}{d} [ \frac{( x + \frac{L}{2} )}{\sqrt{{d}^{2} + {( x + \frac{L}{2} )}^{2}}} - \frac{( x - \frac{L}{2} )}{\sqrt{{d}^{2} + {( x - \frac{L}{2} )}^{2}}} ]} \qquad ( 5 )$$

FIG. 3 shows an embodiment of the linear type evaporator having an opening improved by this way. In practice, even when a linear type evaporator cannot produce a uniform flux, that is, λ(x) is variable, a desired film thickness profile can be achieved by suitably controlling the shape of the opening.

The present invention particularly can be usefully applied in manufacturing a thin film with a uniform thickness but also useful in case of a need for manufacturing a thin film having a relatively simple thickness profile, though not uniform. In fact, features of an evaporator system, that is, various parameters such as the distance between a produced film and a source and the length of a linear type evaporator should be considered in determining the shape of the opening.

The construction capable of controlling the flux by the shape of the opening can be expanded from the linear type evaporator having a 1-dimensional structure to a planar type source having a 2-dimensional structure. Since the surface to be deposited generally has a

In this case, it is also possible to make a planar type source have a desired film thickness profile by control of the opening, as in the linear type evaporator. Similarly to the linear type evaporator, the total flux at a certain position (x, y) on the substrate located at a distance of d over the planar type source is expressed as follows:

$$g ( x , y ) = \int \frac{σ ( {x}^{′} , {y}^{′} ) {Cos}^{n} θ}{{r}^{2}} ⅆ {x}^{′} ⅆ {y}^{′} \qquad ( 6 )$$

where, σ(x′, y′) represents the evaporation rate per unit area of the source, depending on the shape and distribution of the source. Supposing that n=2, the following Expression (7) can be obtained.

$$g ( x , y ) = \int \frac{σ ( {x}^{′} , {y}^{′} ) {d}^{2}}{{[ {( x - {x}^{′} )}^{2} + {( y - {y}^{′} )}^{2} + {d}^{2} ]}^{2}} ⅆ {x}^{′} ⅆ {y}^{′} \qquad ( 7 )$$

FIG. 4a shows a sectional view of a planar type evaporator having this construction. Like general point evaporators or linear type evaporators, the planar type evaporator has a crucible 10 at its lower part. The crucible 10 may be heated by a suitable method, though a heater is not shown in FIG. 4a. Over the crucible 10, a slit plane 30 is disposed. The slit plane 30 comprises a plurality of circular slits or band-shaped slits through which a deposition material passes and is deposited on a substrate.

As in the linear type evaporator, the total area of the slits 31, 32 should be smaller than that of the entire evaporator so that the pressure inside the crucible 10 generates a viscous flow. As a result, gas molecules vigorous collide with each other in the crucible 10 to render pressure distribution throughout the evaporator uniform.

Therefore, even when any local deviation in the evaporation rate exists due to a heater structure and thereby a partial temperature variation, the flux can be uniform throughout the slit plane in the planar type evaporator.

In practice, even when there is a variation in the the slits can be controlled to offset the variation. Similarly to the linear type evaporator film thickness profile in the planar type evaporator can also be controlled by the slits.

As an example for forming a uniform thin film, circular slits 31 and band-shaped slits 32 can be arranged suitably to form a uniform thin film, as shown in FIG. 4a and FIG. 5. A desired thickness profile can be achieved by controlling the arrangement of the circular slits 31 or band-shaped slits 32 having the same slit size, by controlling the slit size of the circular slits 31 or band-shaped slits 32 arranged at a uniform spacing, or by combining the above two method or others. In any case, they are based on the same principle to control geometrical morphology such as the size and arrangement of the slits.

As in the linear type source, the slit width profile w(x, y) for a desired film thickness profile f(x, y) is theoretically determined by the following Expression.

$$w ( x , y ) = \frac{w ( 0 ) f ( x , y )}{g ( x , y )} = \frac{w ( 0 ) f ( x , y )}{\int \frac{σ ( {x}^{′} , {y}^{′} ) {Cos}^{n} θ}{{r}^{2}} ⅆ {x}^{′} {ⅆ}^{′}} \qquad ( 8 )$$

where w(x, y) represents a width at a position with a distance x and y from the center, that is, a function expressed by a distance x and y from the center to a position on the deposited surface to calculate the slit width at that position for obtaining the specific film thickness profile f(x, y), x represents a distance in the x direction to a position on the deposited surface from the center of the deposited surface, y represents a distance in the y direction (perpendicular to the x direction) to a position on the deposited surface from the center of the deposited surface, f(x, y) represents a desired thickness profile function at a position of (x, y) on the deposited surface and σ represents the evaporation rate per unit area of the source.

In the 2-dimensional planar type source, the slit profile can be controlled by both slit width and slit form profile while the slit profile is controlled mostly by slit width in the linear type source.

Industrial Applicability

As apparent from the above description, according to the present invention, in manufacturing a thin film by deposition, it is possible to control the thickness profile of a produced thin film by varying the shape of the slit in the opening of the linear type evaporator, as an example of vacuum evaporators. Also, the present invention can be applied to a planar type evaporator having the same shape with a substrate. As a result, it is possible to effectively perform deposition without movement such as scanning or rotation of a source or a substrate by using the planar type evaporator capable of controlling the thickness profile of a produced thin film. In addition, it is possible to produce the film thickness profile with a desired pattern as well as a uniform thin film.

1. A linear type evaporator capable of controlling film thickness profile comprising:
a crucible formed of an elongate barrel longitudinally extending to a predetermined distance to contain the material to be deposited therein; and
a slit formed on the top surface of the crucible in the longitudinal direction of the crucible and having an area smaller than the sectional area of the crucible or a slit separately installed, thereby performing the deposition of a thin film by moving a substrate in a direction perpendicular to the longitudinal direction of the crucible.

2. The linear type evaporator as set forth in claim 1, wherein the width of the slit is large at both ends and gets narrower toward the center thereof.

3. The linear type evaporator as set forth in claim 1, wherein the width of the slit is calculated by the following Equation:
$$w ( x ) = w ( 0 ) \frac{f ( x )}{g ( x )} = \frac{w ( 0 ) f ( x )}{{\int }_{- L}^{L} \frac{{cos}^{n} θ}{{r}^{2}} λ ( {x}^{′} ) ⅆ {x}^{′}}$$
where w(x) represents a width at a position with a distance of x from the center, that is, a function expressed by a distance x from the center to a position on the deposited surface to calculate the slit width at that position for obtaining the specific film thickness profile f(x), x represents a distance to a position on the deposited surface from the center of the deposited surface, w(0) represents the width of the slit at a datum point, i.e., the center and λ(x) represents an evaporation rate per unit length of the source at a position on the deposited surface with a distance of x from the center of the deposited surface in the longitudinal direction of the evaporator, that is, a function expressed by a distance x from the center to a position for at a position at a distance of x from the center.

4. A planar type evaporator capable of controlling the film thickness profile comprising:
a crucible formed of an elongate cylinder or polygonal prism having a sectional area relatively lager than its height to contain the material to be deposited therein; and
a slit plane formed on the top surface of the crucible in the longitudinal direction of the crucible and having an area smaller than the sectional area of the crucible or a slit plane separately installed, thereby performing the deposition of a thin film.

5. The planar type evaporator as set forth in claim 4, wherein the slit plane includes a plurality of circular slits or narrow band-shaped slits having a predetermined size, in which the circular slits or narrow band-shaped slits are arranged more densely toward the periphery of the slit plane than the center.

6. The planar type evaporator as set forth in claim 4, wherein the slit plane includes a plurality of circular slits or narrow band-shaped slits, in which the size of the circular slits or narrow band-shaped slits is getting greater toward the periphery of the slit plane than the center.

7. The evaporator as set forth in claim 5 or 6, wherein the slit width profile w(x, y) for a desired film thickness profile f(x, y) is theoretically determined by the following Expression:
$$w ( x , y ) = \frac{w ( 0 ) f ( x , y )}{g ( x , y )} = \frac{w ( 0 ) f ( x , y )}{\int \frac{σ ( {x}^{′} , {y}^{′} ) {Cos}^{n} θ}{{r}^{2}} ⅆ {x}^{′} ⅆ {y}^{′}}$$
where w(x, y) represents a function for the slit width and profile expressed by a distance x and y from the center to a position on the deposited surface, x represents a distance in the x direction to a position on the deposited surface from the center of the deposited surface, y represents a distance in the y direction (perpendicular to the x direction) to a position on the deposited surface from the center of the deposited surface, f(x, y) represents a desired thickness profile function at a position of (x, y) on the deposited surface and σ represents the evaporation rate per unit area of the source.

8. The evaporator as set forth in claim 6, wherein the slit width profile w(x, y) for a desired film thickness profile f(x, y) is theoretically determined by the following Expression:
$$w ( x , y ) = \frac{w ( 0 ) f ( x , y )}{g ( x , y )} = \frac{w ( 0 ) f ( x , y )}{\int \frac{σ ( {x}^{′} , {y}^{′} ) {Cos}^{n} θ}{{r}^{2}} ⅆ {x}^{′} ⅆ {y}^{′}}$$
where w(x, y) represents a function for the slit width and profile expressed by a distance x and y from the center to a position on the deposited surface, x represents a distance in the x direction to a position on the deposited surface from the center of the deposited surface, y represents a distance in the y direction (perpendicular to the x direction) to a position on the deposited surface from the center of the deposited surface, f(x, y) represents a desired thickness profile function at a position of (x, y) on the deposited surface and σ represents the evaporation rate per unit area of the source
